(19) United States
(12) Patent Application Publication
(10) Pub. No.: US 2005/0258459 A1
(43) Pub. Date: Nov. 24, 2005

(54) Method for fabricating semiconductor devices having a substrate which includes group III-nitride material

(76) Inventors: Kiuchul Hwang, Amherst, NH (US); Thomas Kazior, Sudbury, MA (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(21) Appl. No.: 10/848,036

(22) Filed: May 18, 2004

(51) Int. Cl. H01L 29/812; H01L 21/338

(52) U.S. Cl. 257/280; 438/167; 438/572; 438/604; 257/615

(57) ABSTRACT

A method for fabricating a device having a substrate comprising III-N material, such as gallium nitride or aluminum gallium nitride. A surface of the substrate comprising group III-N is oxidized to form an oxide layer comprising III-oxide or III-oxynitride. The layer is formed with a predetermined thickness. Portions of the substrate disposed beneath the upper surface portion remaining un-oxidized. Electrical contacts are formed in ohmic contact without first surface portions of the substrate. An electrical contact is formed in Schottky contact with another surface portion of the substrate after the oxide layer is selectively removed from the upper portion of the substrate.

### TECHNICAL FIELD

This invention relates to methods for fabricating semiconductor devices, and more particularly to methods for fabricating semiconductor devices having a substrate which includes a Group III-nitride (i.e., III-N) material, such as gallium nitride and aluminum gallium nitride material.

### BACKGROUND

As is known in the art, III-N material substrates, such as, for example, gallium nitride (GaN) and gallium aluminum nitride (AlGaN) substrates have been suggested for use in the fabrication of semiconductor devices. In the processing for these devices, the exposed surface of the III-N material substrate goes through a series of process steps during the fabrication of the device, e.g., FETs such as MESFETs or HEMTs. These process steps include photoresist coating/baking, chemical cleaning, high temperature alloying, and oxygen and argon plasma etching. Because of these processing steps, the exposed III-N surface is damaged resulting in defected surfaces and causing device degradation.

As is also known in the art, one of the key processes which has affected the reliability of the device is the formation of the gate. The gate metal is supposed to be contacting a defect-free semiconductor surface to form a Schottky barrier. When the gate metal is contacting a damaged surface, however, rather than a pristine III-N material substrate surface, the function of the Schottky barrier is degraded resulting in poor electrical performance. In addition to the adverse effect of the damaged gate area, damage to the exposed surface area between gate and drain/source causes long term device performance and reliability degradation due to high electric field formation between gate and drain. Various techniques have been suggested to reduce the above-described surface damage. These techniques have been focused on improving the quality of dielectric passivation layers such as silicon nitride, silicon oxide, and aluminum nitride, on exposed GaN or AlGaN surfaces (i.e., the area between drain and source).

### SUMMARY

In accordance with the present invention, a method is provided for fabricating a device having a substrate comprising a Group III-nitride material. An upper surface of the substrate is oxidized to form an oxide layer comprising a III-oxide or III-oxynitride material. The layer is formed with a predetermined thickness. Portions of the substrate disposed beneath the upper surface remain un-oxidized. Electrical contacts are formed in ohmic contact with first surface portions of un-oxidized surface portions of the substrate. An electrical contact is formed in Schottky contact with a second un-oxidized surface portion of the substrate.

With such method, the oxide layer is a natural film grown directly from the substrate. Therefore, there is absolutely no surface damage during the generation of the film, i.e., oxide layer. The grown oxide layer is easily removed by regular wet etching chemicals during FET or HEMT process steps. The oxide layer is also able to sustain high temperature process and chemical cleaning, and protects the pristine III-N surface from the high temperature and chemical cleaning. Therefore, with such method, reliability issues related to the series of process steps are completely eliminated.

In one embodiment, the III-N material is gallium nitride or aluminum gallium nitride.

In one embodiment, the method includes oxidizing an upper surface of a substrate comprising a III-N material form an oxide layer comprising a III-oxide or III-oxynitride material. The layer is formed with a predetermined thickness. Portions of the substrate disposed beneath the upper oxidized surface portion remain un-oxidized. A first mask is provided over the formed oxide layer, such mask having windows therein to expose portions of the formed oxide layer. During a first etching process, an etch is brought into contact with the exposed portions of the formed oxide layer to remove such exposed portions of the formed oxide layer thereby exposing underlying portions of the un-oxidized upper surface portion of the substrate. Electrical contacts are formed in ohmic contact with the exposed un-oxidized upper surface portions of the substrate and the first mask is removed. A second mask is provided over the electrical contacts. The second mask has a window disposed over a portion of the formed oxide layer and between the electrical contacts thereby exposing underlying portions of the oxide layer. During a second etching process, an etch is brought into contact with the exposed portions of the formed oxide layer to remove such exposed portions of the formed oxide layer thereby exposing underlying portions of the un-oxidized upper surface portion of the substrate. An electrical contact is formed in Schottky contact with the exposed un-oxidized upper surface portion of the substrate.

In one embodiment, the etch used during the first etching process is a wet etch.

In one embodiment, the etch used during the second etching process is a wet etch.

In one embodiment, the forming electrical contacts in ohmic contact with the exposed un-oxidized upper surface portion of the substrate comprises depositing a metal onto the exposed un-oxidized upper surface portion of the substrate and alloying such metal with the exposed un-oxidized upper surface portion of the substrate.

In one embodiment, the first mask provided over the formed oxide layer comprises forming a layer of photoresist and baking such layer of photoresist.

In one embodiment, the second mask over the formed oxide layer comprises forming a second layer of photoresist and baking such second layer of photoresist.

In accordance with another feature of the invention, a semiconductor device is provided having a substrate comprising III-N material. An oxide layer comprising III-oxide or III-oxynitride is disposed on first and second portions of a surface of the substrate. The layer has a predetermined thickness. A source electrode and a drain electrode are in ohmic contact with the substrate. A gate electrode is in Schottky contact with the substrate. The gate electrode is disposed between the source electrode and the drain electrode. The first portion of the oxide layer is disposed between the gate electrode and the source electrode and the second portion of the oxide layer is disposed between the gate electrode and the drain electrode.

In one embodiment, the III-N material is gallium nitride or aluminum gallium nitride.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIGS. 1 through 12 show cross-sectional views of a sketch of a semiconductor device at various stages in the fabrication thereof in accordance with the invention.

Like reference symbols in the various drawings indicate like elements.

### DETAILED DESCRIPTION

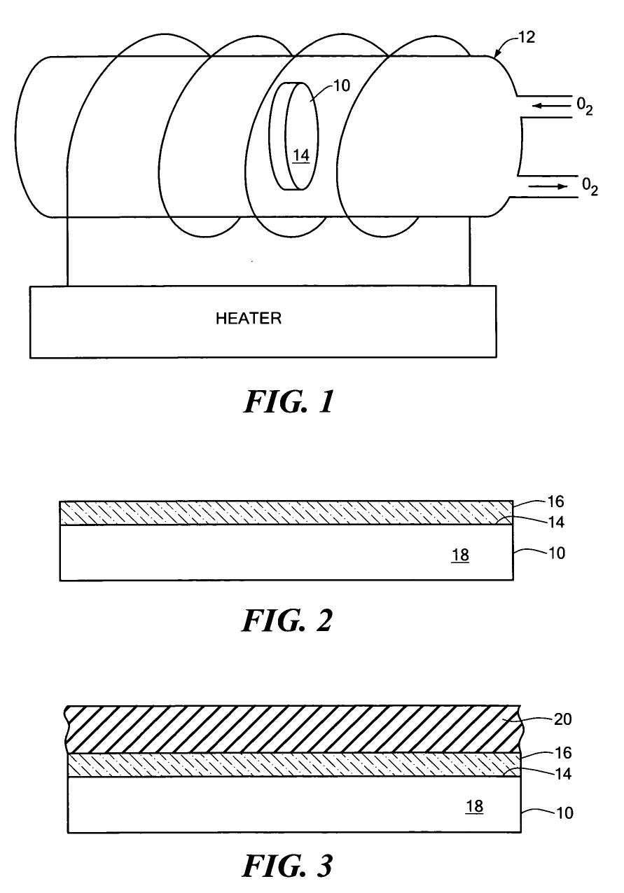

Referring now to FIG. 1, a semiconductor substrate 10, here such substrate comprising Group III-nitride material (i.e., III-N) such as gallium nitride (GaN), or aluminum gallium nitride (AlGaN) is disposed in heated, oxidation furnace 12. The furnace 10 is fed oxygen gas, O₂, as indicated, and heated to a temperature to thereby thermally grow, i.e., oxidize, the surface 14 of subsrtate 10 and thereby form an oxide layer 16 on the upper surface of the substrate 10, as shown in FIG. 2. Thus, here the oxide layer 16 is Group III-oxide or Group III-oxynitride, such as gallium oxide or gallium oxynitride. It is noted that the oxide layer 16 is grown to a predetermined thickness.

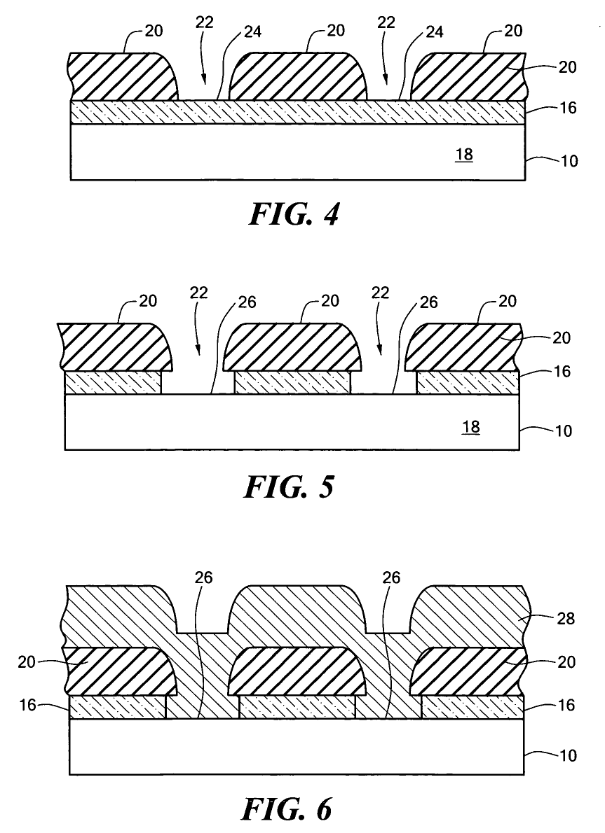

It is noted that the oxide layer 16 is a natural film grown directly from the substrate 10. Therefore, there is absolutely no surface damage during the generation of the film, i.e., oxide layer 16. It is also noted that portions 18 of the substrate 10 disposed beneath the upper surface portion 14 remaining un-oxidized, i.e., pristine III-N when a III-N substrate 10 is used. Next, referring to FIG. 3, a mask 20 is disposed over the formed oxide layer 16. The mask 20 is a photoresist layer, baked and processed to have windows 22 therein to expose portions 24 of the formed oxide layer 16, as shown in FIG. 4.

Referring to FIG. 5, during a first etching process, an etch is brought into contact with the exposed portions 24 (FIG. 4) of the formed oxide layer 16 to remove such exposed portions 24 of the formed oxide layer 16 thereby exposing underlying portions 26 of the un-oxidized upper surface portion 18 of the substrate 10. Here, the etch is a wet acid or base etch such as, for example, hydrofluoric Acid. It is noted that the wet etching rate between the oxidized layer and the un-oxidized layer is significant different so that the undercut of the oxidized layer can be controlled by the etching rate and the thickness of the oxide layer. Thus, the size of the windows 22 (FIG. 5) and the time duration of the etch are selected so that the surface area of the surface portions 26 results in a desired size.

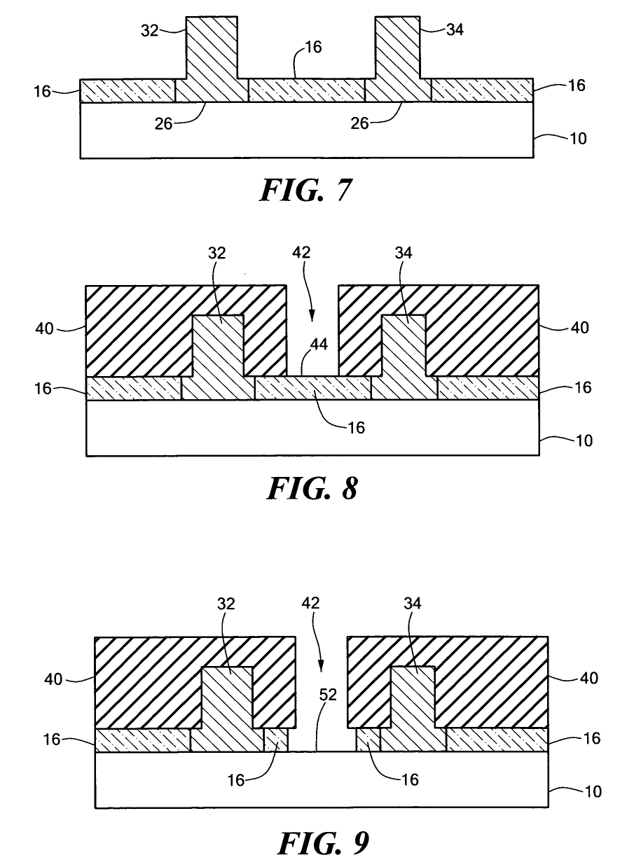

Referring now to FIG. 6, a layer 28 of metal is deposited over the surface of the structure shown in FIG. 5. It is noted that portions of the metal 28 are in contact with the exposes underlying portions 26 of the un-oxidized upper surface portion 18 of the substrate 10. Next, the photoresist layer 20 is lifted thereby leaving portions of the metal layer to thereby form the electrical contacts 32, 34 as shown in FIG. 7. The structure is heated to thereby alloy the metal electrodes 32, 34 with the portions 26 of the substrate 10. It is noted that during this alloying, a portion of the oxide layer 16 remains over the substrate 10 in the region between the electrical contacts 32, 34. The alloying thereby forms the electrical contacts 32, 34 in ohmic contact with the substrate 10. As will be seen, the electrical contacts 32, 34 will provide source and drain electrodes for a FET device. Thus, the surface region of the substrate 10 between the source and drain electrodes 32, 34 is protected by the oxide layer 16 during the photoresist bake and during the alloying processes.

Next, referring to FIG. 8, a second mask 40, here made from a photoresist layer, is provided over the electrical contacts 32, 34. The second photoresist mask 40 has a window 42 disposed over a portion 44 of the formed oxide layer 16 and between the electrical contacts 32, 34 thereby exposing the underlying portion 44 of the formed oxide layer 16.

Referring now to FIG. 9, during a second etching process, an etch is brought into contact with the exposed portion 44 (FIG. 8) of the formed oxide layer 16 to remove such exposed portion 44 of the formed oxide layer 16 thereby an exposing underlying portion 52 of the un-oxidized upper surface portion of the substrate 10. Here, the etch is a wet acid or base etch such as, for example, hydrofluoric Acid. It is noted that the wet etching rate between the oxidized layer 16 and the un-oxidized layer is significant different so that the under cut of the oxide layer can be controlled by the etching rate and the thickness of the oxide layer. Thus, the size of the windows 42 (FIG. 8) and the time duration of the etch are selected so that the surface area of the surface portions 52 results in a desired size, here the desired gate channel length.

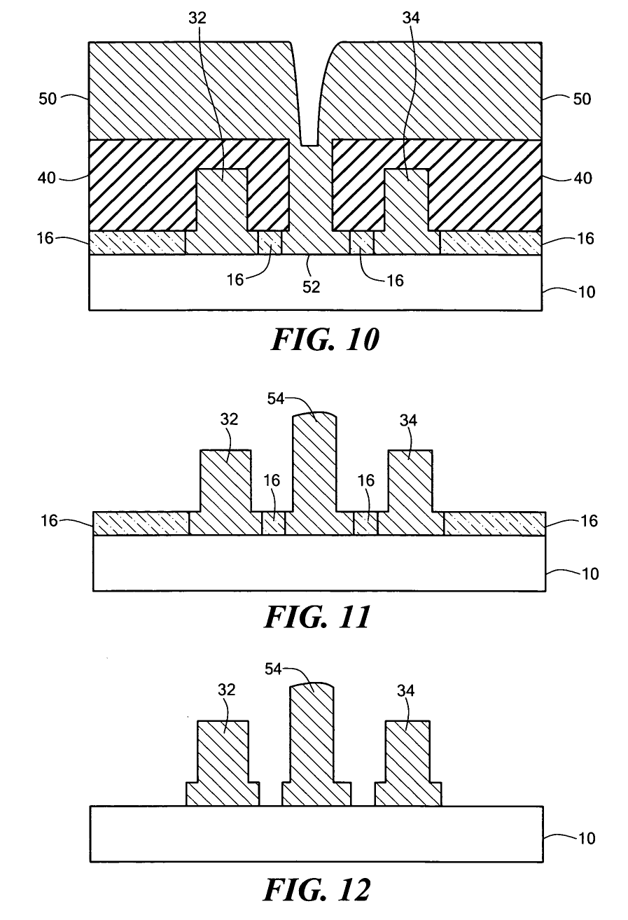

Referring now to FIG. 10, a layer 50 of metal is deposited over the surface of the structure shown in FIG. 9. It is noted that portions of the metal 50 are in contact with the exposes underlying portions 52 of the un-oxidized upper surface portion 18 of the substrate 10.

Next, the photoresist layer 50 is lifted thereby leaving portions of the metal layer to thereby form the electrical contact 54, as shown in FIG. 11. The electrical contact 54, here a gate electrode, is formed in Schottky contact with the portion 52 of the un-oxidized portion of the substrate 10.

Referring now to FIG. 12, the oxide layer 16, FIG. 11, is etched to produce the structure shown.

A number of embodiments of the invention have been described. Nevertheless, it will be understood that various modifications may be made without departing from the spirit and scope of the invention. Accordingly, other embodiments are within the scope of the following claims.

1. A method for fabricating a device having a substrate comprising Group III-nitride:
oxidizing an upper surface of the substrate to form an oxide layer, such layer being formed with a predetermined thickness, portions of the substrate disposed beneath the upper surface portion remaining un-oxidized;
forming electrical contacts in ohmic contact with first un-oxidized surface portions of the substrate;
forming an electrical contact in Schottky contact with another un-oxidized surface portion of the substrate.

2. The method recited in claim 1 wherein oxidizing of the substrate forms the oxide layer as a layer of such as Group III-oxide of Group III-oxynitride.

3. The method recited in claim 2 wherein the Group III material is gallium nitride or aluminum gallium nitride.

4. The method recited in claim 3 wherein the oxide layer is a gallium nitride or gallium oxynitride.

5. A method for fabricating a device having a substrate comprising III-N material, comprising:
oxidizing a surface of the substrate to form an oxide layer on a upper surface portion of the substrate, such layer being formed with a predetermined thickness, portions of the substrate disposed beneath the upper surface portion remaining un-oxidized;
providing a first mask over the formed oxide layer, such mask having windows therein to expose portions of the formed oxide layer;
during a first etching process, bringing a first etch into contact with the exposed portions of the formed oxide layer to remove such exposed portions of the formed oxide layer thereby exposing underlying portions of the un-oxidized upper surface portion of the substrate;
forming electrical contacts in ohmic contact with the exposed un-oxidized upper surface portions of the substrate including removing the first mask;
providing a second mask over the electrical contacts, such second mask having a window disposed over a portion of the formed oxide layer and between the electrical contacts thereby exposing underlying portions of the oxide layer;
during a second etching process, bringing a second etch into contact with the exposed portions of the formed oxide layer to remove such exposed portions of the formed oxide layer thereby exposing underlying portions of the un-oxidized upper surface portion of the substrate oxide layer;
forming an electrical contact in Schottky contact with the exposed portions of the the un-oxidized upper surface portion of the substrate.

6. The method recited in claim 5 wherein the first etch used during the first etching process is a wet etch.

7. The method recited in claim 5 wherein the second etch used during the second etching process is a wet etch.

8. The method recited in claim 7 wherein the first etch used during the first etching process is a wet etch.

9. The method recited in claim 5 wherein the forming electrical contacts in ohmic contact with the exposed un-oxidized upper surface portion of the substrate comprises:
depositing a metal onto the exposed un-oxidized upper surface portion of the substrate and alloying such metal with the exposed un-oxidized upper surface portion of the substrate.

10. The method recited in claim 5 wherein providing the first mask over the formed oxide layer comprises forming a layer of photoresist and baking such layer of photoresist.

11. The method recited in claim 10 wherein the first etch used during the first etching process is a wet etch.

12. The method recited in claim 11 wherein the forming electrical contacts in ohmic contact with the exposed un-oxidized upper surface portion of the substrate comprises:
depositing a metal onto the exposed un-oxidized upper surface portion of the substrate and alloying such metal with the exposed un-oxidized upper surface portion of the substrate.

13. The method recited in claim 12 wherein providing the second mask over the formed oxide layer comprises forming a second layer of photoresist and baking such second layer of photoresist.

14. The method recited in claim 11 wherein the second etch used during the second etching process is a wet etch.

15. A semiconductor device, comprising:
a substrate comprising III-N material;
an oxide layer comprising III-oxide or III-oxynitride on first and second portions of a surface of the substrate, such layer having a predetermined thickness;
a source electrode and a drain electrode in ohmic contact with the substrate;
a gate electrode in Schottky contact with the substrate;
wherein the gate electrode is disposed between the source electrode and the drain electrode;
wherein the first portion of the oxide layer is disposed between the gate electrode and the source electrode and the second portion of the oxide layer is disposed between the gate electrode and the drain electrode.

16. The semiconductor device recited in claim 15 wherein the III-N material is gallium nitride or aluminum gallium nitride
